(19) United States
(12) Patent Application Publication
(10) Pub. No.: US 2024/0300284 A1
(43) Pub. Date: Sep. 12, 2024

(54) SYSTEM AND METHOD FOR DYNAMIC FLUID HEATING IN ELECTRIC VEHICLES

(71) Applicant: MICROHEAT TECHNOLOGIES PTY LTD, Mulgrave (AU)

(72) Inventors: Cedric Israelsohn, Mulgrave (AU); Brett Hernadi, Mulgrave (AU); Ian William Taig, Mulgrave (AU)

(21) Appl. No.: 18/575,131

(22) PCT Filed: Apr. 8, 2022
(86) PCT No.: PCT/AU2022/050316

§ 371 Date: Dec. 28, 2023

(30) Foreign Application Priority Data
Jun. 28, 2021 (AU) 2021901956

(51) Int. Cl. B60H 1/00; B60H 1/22

(52) U.S. Cl. CPC B60H 1/00278; B60H 1/00428; B60H 1/2221; B60H 2001/2265

(57) ABSTRACT

A system and method for heating a vehicle component is provided and comprises one or more cells for retaining a fluid, each cell including one or more electrode pairs positioned therein. The one or more cells are arranged along a flow path including an inlet to and an outlet from the one or more cells. A controller is provided which is configured to: regulate the flow of the fluid from the inlet to the one or more cells; determine at the one or more cells the electrical conductivity, or specific conductance, of the fluid; determine from the electrical conductivity, or specific conductance, of the fluid a voltage to apply from a high voltage battery, or an external power source located outside of the vehicle, across the one or more electrode pairs at a current sufficient to heat the fluid therein; and pass the current from the one or more electrode pairs to the fluid to produce a heated fluid, wherein the heated fluid transfers heat to one or more vehicle components via the outlet.

### TECHNICAL FIELD

The present invention relates to a method and device for heating a fluid and more particularly, to heating a thermally conductive mixture in a vehicle.

### BACKGROUND OF INVENTION

Electric and hybrid electric vehicles are becoming increasingly desirable to vehicle owners. One of the most prominent benefits of electric vehicle use includes eliminating potentially harmful greenhouse gas emissions exhausted by an internal combustion engine. Furthermore, battery technology has advanced such that a reasonably sized battery pack can provide enough range and acceleration acceptable to a large proportion of drivers. To provide a usable electric vehicle, the battery pack must also be efficiently charged (ideally, as quickly as possible) and discharged many times.

One challenge facing electric vehicle designers includes the sensitivity of the key electric vehicle components that includes the high voltage batteries, to temperature. More specifically, the maximum charge current and the maximum discharge current of the batteries vary based on battery temperature, among other things. The temperature of the battery may vary during operation due to chemical reactions taking place within the battery as well as the ambient temperature of the environment in which the vehicle is positioned. For example, the maximum charging current and the operational longevity of a battery may be significantly reduced if charging occurs when the temperature of the battery is below a predetermined limit. Battery charging and discharging efficiency and battery operational longevity may also be less than optimal when the temperature of the battery is above a predetermined operating limit. Maintaining the key electric vehicle components at an optimum operating temperature is vital and may be achieved with effective thermal management. Effective thermal management may improve key component operational performance and longevity.

Furthermore, existing heaters for vehicle combustion engines may not be suited to warm an electric vehicle battery pack. Many existing engine block heaters are energized by a 12 V or 24 V power supply. The watt-density of the heating element is defined accordingly. While these heaters perform a desired function, they may not be simply installed within an electric vehicle equipped with a high voltage power supply in the range of about 450 VDC. Controlling the heaters associated with the high voltage circuit also becomes very important to assure that an overheating condition of the key vehicle components is avoided. Therefore, it may be beneficial to provide a temperature control system that is able to maintain the desired optimum temperature for each of the key electric vehicle components, more specifically, the high voltage battery.

Heaters which make use of a liquid coolant as the fluid to be heated and have heating elements for generating the heat that must then be transferred to the liquid coolant are known. The liquid coolant is identified as liquid to be heated since these types of liquids are those normally used and are formulated to withstand high and very low temperatures, to have good heat capacity and thermal conductivity in order to deliver the required thermal management and include additives maintain required levels of thermal conductivity and also keep the conduits through which it circulates in good condition. Nevertheless, the liquid to be heated will hereinafter be generically referred to as fluid or thermal fluid.

An example of a known heater is shown in US20120295141. That document describes a coolant heater including a housing, a heating element and a thermistor. The heater is suitable for heating an electric vehicle battery. The element is in a heat transfer relationship with coolant retained in the housing, much like a kettle. The element is a resistive heating element manufactured in a particular geometry to provide a desired watt density (in that case, around 30 watts per square centimetre, making it relatively large to achieve a requisite 5000 watts, or more, for most vehicle applications). Ideally, coolant heaters have to be as small as possible, weigh as little as possible, and be so designed as to take up as little space as possible to allow for installation optimisation and also where said space saving can be used for other elements, such as battery storage.

To heat the coolant, power is selectively supplied (and not supplied) to the element using pulse width modulation. Such a control strategy may reduce the overall quantity of energy provided to the element over a prolonged operating period and may provide closed-loop control of the heater function based on the signal provided by the thermistor. However, heating the element by pulse width modulation together with the overall design makes the heater prone to the effects of thermal inertia, making it very difficult to dynamically and accurately control the temperature of a coolant circuit delivering a less than adequate thermal management strategy. Further, surface temperatures of the housing can be very hot (in the order of +300° C.) as there is significant heat exchange between the coolant and the housing making them unsuitable for certain locations within a vehicle, for example, proximate to sensitive electronic components, or indeed the battery itself, where it may cause damage.

Attempts have been made to cure some of these deficiencies and thereby improve overall thermal management efficacy through the use of a thick film heating elements e.g., polymer PTC heating elements. However, while the problem of thermal inertia with such designs is improved, it is still a key issue for responsive energy and effective coolant thermal management.

It is also known that where a heating element contacts water (as is the case with both concepts), unless the element is coated with a material that prevents scale forming and/or the water is filtered, scale will tend to form on the element. When scale forms on a heating element, it makes the element less efficient as a heater and may result in permanent damage to the heating element.

It would be desirable to provide a system and method which ameliorates or at least alleviates one or more of the above problems or to provide an alternative.

It would also be desirable to provide a system and method that ameliorates or overcomes one or more disadvantages or inconvenience of known vehicle fluid heating systems and methods, particularly electric vehicles.

A reference herein to a patent document or other matter which is given as prior art is not to be taken as an admission or a suggestion that the document or matter was known or that the information it contains was part of the common general knowledge as at the priority date of any of the claims.

### SUMMARY OF INVENTION

According to an aspect of the present invention, there is provided a system for heating a vehicle component, the system comprising: one or more cells for retaining a fluid, each cell including one or more electrode pairs positioned therein; the one or more cells arranged along a flow path including an inlet to and an outlet from the one or more cells; a controller configured to: regulate the flow of the fluid from the inlet to the one or more cells; determine at the one or more cells the electrical conductivity, or specific conductance, of the fluid; determine from the electrical conductivity, or specific conductance, of the fluid a voltage to apply from a high voltage battery, or an external power source located outside of the vehicle, across the one or more electrode pairs at a current sufficient to heat the fluid therein; and pass the current from the one or more electrode pairs to the fluid to produce a heated fluid, wherein the heated fluid transfers heat to one or more vehicle components via the outlet. The one or more heating cells may not only retain, but also facilitate the flow-through of the fluid. The one or more electrode pairs may be formed by sectioning a single electrode pair into a plurality of electrode section pairs or segments, each segment having its own effective surface area. The effective surface areas may be the same or different sizes.

Advantageously, the system is suitable for heating fluids by passing current from the one or more electrode pairs to the fluid. The system is dynamic and not prone to thermal inertia, thus making it suitable for passing cooled fluids through. For example, from a battery cooling subsystem coupled to a coolant loop containing a coolant (i.e., a heat transfer medium). That is, the cooling loop may also be thermally coupled to system, thus ensuring that the temperature of the battery can be maintained within its preferred operating range regardless of the ambient temperature.

The voltage applied to the electrodes may be direct current (DC). In either case, the electrical power source may be supplied by a battery. However, an alternating current (AC) may also be used in some embodiments, whereby the power may be supplied by a single phase or three phase power supply external to the vehicle. Various electronic components may be provided to switch between power supplies.

In one or more embodiments, the one or more cells for retaining the fluid are in proximity to the one or more vehicle components. Due to the high operating voltages and relatively high conductivity of a typical coolant solution of water and ethylene glycol mixture, the system can have a very compact and lightweight form factor making it possible to position very closely to temperature sensitive components without running long and complex thermal circuits or loops.

In one or more embodiments, the one or more vehicle components includes one of more of the high voltage battery, a DC motor, a heating, ventilation, and air conditioning (HVAC) system, and drive electronics. It will be appreciated that the system may be coupled to the various possible configurations of the heat exchange that are known in the art, including: thermal jackets, thermal plates containing specifically designed fluid passages, heatsinks, radiators, finned inserts, and the like.

In one or more embodiments, the specific conductance of the fluid is greater than that of water. Advantageously, this results in smaller electrodes and a more compact system overall. The specific conductance of the fluid may be in the range of from about 2,500 to 5,000 μS/cm and includes a water and ethylene glycol mixture.

In one or more embodiments, the controller monitors properties of the mixture including ethylene glycol quality or ethylene glycol concentration. This may be performed measuring the electric current drawn by the mixture. Advantageously, the properties may provide advanced diagnostic features through on-board diagnostic (OBD) ports or over-the-air (e.g., using various types of wireless communication techniques). The properties may relate to the quality and concentration of ethylene glycol mixture.

In one or more embodiments, the controller monitors ethylene glycol mixture quality or ethylene glycol mixture concentration to maintain the desired thermal conductivity of the mixture.

In one or more embodiments, the controller is configured to manage the thermal conductivity of the mixture by monitoring the specific conductance of the ethylene glycol mixture. The controller may be configured to deliver dynamic and effective thermal management of the mixture thereby ensuring that an optimum operating temperature of the one or more vehicle components is maintained.

In one or more embodiments, the controller is configured to manage the thermal conductivity of the mixture thereby ensuring that an optimum operating temperature of the one or more vehicle components is maintained.

In one or more embodiments, the high voltage battery is a lithium-ion battery used for vehicle propulsion in a hybrid vehicle or a battery electric vehicle (BEV). Charging of electric vehicle lithium-ion (Li-ion) battery cells can be challenging due to constraints related to performance or degradation of the battery. For example, under some conditions (e.g., at specific temperatures), charging of the Li-ion battery can cause the deposition of lithium onto the anode of the battery. Lithium deposition on the anode can lead to performance degradation such as, shorter charging cycles, shorter battery life, or internal short-circuiting of the cell. The internal short-circuiting of the cell can lead to heat generation that can cause battery cell failure.

In one or more embodiments, the controller is further configured to determine the electrical conductivity, or specific conductance of the fluid and thereby determine the voltage to apply across the one or more electrode pairs continuously. The controller may be further configured to deliver the dynamic thermal management required by determining the electrical conductivity, or specific conductance of the fluid and in determining the voltage to apply across the one or more electrode pairs continuously, deliver dynamic and effective thermal management.

In one or more embodiments, the one or more electrode pairs are segmented into two or more segments, each configured segment being selected by the controller to be individually electrically energised. Individually applying the voltages across the two or more segments increases or decreases the effective surface area of the one or more electrode pairs. Advantageously the conductivity or specific conductance gradient is thereby managed. By activating individual segments of the segmented electrodes may be performed in a manner to effect very accurate delivery of desired current and voltage by the segmented electrodes. Each segmented electrode may be divided into segments of varying size, to permit combinations of segments to be selected to provide an increased accuracy of selection of desired effective area. For example, where the segmented electrode is divided into three segments, the segments may have relative effective areas in a ratio of 1:2:4, that is, the segments preferably constitute four sevenths, two sevenths and one seventh of the total effective electrode area, respectively. In such embodiments, appropriate activation of the three electrode segments permits selection of any one of seven available effective areas. Alternative segment area ratios and numbers of segments may be provided. For example, the one or more electrode pairs are segmented into n segments each having effective surface areas in a ratio of 1:2: . . . :2(n−1).

In one or more embodiments, the voltage across the two or more segments increases or decreases the effective electric current drawn by the fluid by virtue of electrode surface area. An initial voltage may be determined such that the current drawn by the fluid upon application of the voltage across the one or more electrode pairs does not exceed a peak current rating of the electrical supply or the peak current rating of the supply power control devices supplying voltage to the electrode pairs. The peak current rating may be the most current that the electrical supply can handle without tripping or suffering damage or irreversible damage. Advantageously, this may also provide protection to the electrical supply (expensive and potentially flammable in vehicles) and power control devices supplying voltage to the electrode pairs.

In one or more embodiments, the two or more segments are of uniform size.

In one or more embodiments, the two or more segments are of different sizes.

In one or more embodiments, the one or more electrode pairs are segmented into n segments each having effective surface areas in a ratio of 1:2: . . . :2(n−1).

In one or more embodiments, the one or more electrode pairs are substantially parallel and positioned in a generally horizontal plane relative to the flow path.

In one or more embodiments, the one or more electrode pairs are substantially vertical and positioned in a generally vertical plane relative to the flow path.

In one or more embodiments, the one or more electrode pairs are at least in part coated with an inert electrically conductive material or a non-metallic conductive material including a conductive plastics material, carbon impregnated material, and combinations thereof. Advantageously, the material is capable of withstanding prolonged exposure to the mixture of ethylene glycol and water without scale build-up or corrosion.

In one or more embodiments, the one or more electrode pairs are formed at least in part from a material selected from the group consisting of metal or a non-metallic conductive material. The materials may include a layered structure and included various binding materials.

In one or more embodiments, the one or more electrode pairs are formed from an electrically conductive, inert material including graphite, carbon, and combinations thereof.

In one or more embodiments, the controller is further configured to measure a flow rate of the fluid flowing through the flow path.

In one or more embodiments, the controller is further configured to increase or decrease the flow rate of the fluid flowing through flow path to regulate a residency time of the fluid in the one or more cells. The residency time for which a given volume of the fluid will receive electrical power from the electrodes may be determined by measuring the flow rate of the fluid through the passage. The flow rate may be also limited by one or more threshold values associated with the flow rate and/or the pumping or regulation of the fluid.

In one or more embodiments, the controller is further configured to measure a temperature of the fluid flowing through the flow path.

In one or more embodiments, the controller is further configured to measure the temperature of the fluid at the outlet; and provide the temperature as feedback to a temperature controller configured to increase or reduce heating of the fluid.

In one or more embodiments, the one or more one or more cells are serially arranged along the flow path.

In one or more embodiments, the controller is further configured not to apply the voltage across the one or more electrode pairs if the electrical conductivity, or specific conductance of the fluid falls outside a predetermined range. Advantageously, this may also provide protection to the electrical supply and power control devices supplying voltage to the electrode pairs.

In one or more embodiments, the inlet and outlet extend at substantially ninety degrees to each other.

In one or more embodiments, the system may further include a pump providing pressurized fluid in thermal communication with the one or more vehicle components.

In one or more embodiments, the controller includes a vehicle bus that communicates with other vehicle systems. The vehicle bus may include LIN (Local Interconnect Network) a very low cost in-vehicle sub-network.

In one or more embodiments, the battery voltage is in the range from about 250 to about 450 VDC. Advantageously, a high voltage reduces the gauge of wire required onboard the vehicle, which has weight and space saving advantages further contributing the compact and lightweight design.

In one or more embodiments, the one or more cells for retaining a fluid is made from an electrically non-conductive light weight plastic material.

Advantageously, the light weight plastic material reduces the overall weight of the system. Additionally, plastic being an insulator means surface temperatures of any housings will not be very hot. That is, there is insignificant heat exchange between the fluid and the housing making it suitable for certain locations within a vehicle, for example, proximate to sensitive electronic components, or indeed the battery itself, where it will not cause damage.

In one or more embodiments, the system is rated to be operable up to about 9 kW.

According to another aspect of the present invention, there is provided a method for heating a vehicle component, the method comprising the steps of: providing an electrical connection to a high voltage battery being at least partially used for vehicle propulsion; providing one or more cells for retaining a fluid, each cell including one or more electrode pairs positioned therein; arranging the one or more cells along a flow path, the flow path including an inlet to and an outlet from the one or more cells; determining at the one or more cells the electrical conductivity, or specific conductance, of the fluid; determining from the electrical conductivity, or specific conductance, of the fluid a voltage to apply from the high voltage battery, or an external power source located outside of the vehicle, across the one or more electrode pairs at a current sufficient to heat the fluid therein; and passing the current from the one or more electrode pairs to the fluid to produce a heated fluid, wherein the heated fluid transfers heat to one or more vehicle components via the outlet.

In one or more embodiments, the one or more cells for retaining the fluid are provided in proximity to the one or more vehicle components.

In one or more embodiments, the one or more vehicle components includes one of more of the high voltage battery, a DC motor, a heating, ventilation, and air conditioning (HVAC) system, and drive electronics.

In one or more embodiments, the specific conductance of the fluid is greater than that of water.

In one or more embodiments, the specific conductance of the fluid is in the range of from about 2,500 to 5,000 μS/cm.

In one or more embodiments, the fluid includes a water and ethylene glycol mixture.

In one or more embodiments, the method further comprises the step of monitoring properties of the mixture including water ethylene glycol mixture quality or water ethylene glycol mixture concentration.

In one or more embodiments, the high voltage battery is a lithium-ion battery used for vehicle propulsion in a hybrid vehicle or a battery electric vehicle (BEV).

In one or more embodiments, the steps of determining the electrical conductivity, or specific conductance of the fluid and determining the voltage to apply across the one or more electrode pairs are performed continuously along the flow path.

In one or more embodiments, the one or more electrode pairs are segmented into two or more segments, each segment being configured to individually apply voltage to the fluid.

In one or more embodiments, individually applying the voltage across the two or more segments increases or decreases the effective electric current drawn by the fluid by virtue of electrode surface area.

In one or more embodiments, the two or more segments are of uniform size.

In one or more embodiments, the two or more segments are of different sizes.

In one or more embodiments, the one or more electrode pairs are segmented into n segments each having effective surface areas in a ratio of 1:2: . . . :2 (n−1).

In one or more embodiments, the one or more electrode pairs are substantially parallel and positioned in a generally horizontal plane relative to the flow path.

In one or more embodiments, the one or more electrode pairs are substantially vertical and positioned in a generally vertical plane relative to the flow path.

In one or more embodiments, the one or more electrode pairs are at least in part coated with an inert electrically conductive material or a non-metallic conductive material including a conductive plastics material, carbon impregnated material, and combinations thereof.

In one or more embodiments, the one or more electrode pairs are formed at least in part from a material selected from the group consisting of metal or a non-metallic electrically conductive material.

In one or more embodiments, the one or more electrode pairs are formed from an electrically conductive, inert material including graphite, carbon, and combinations thereof.

In one or more embodiments, the method further comprises the step of measuring a flow rate of the fluid flowing through the flow path.

In one or more embodiment, the method further comprises the step of increasing or decreasing the flow rate of the fluid flowing through the flow path to regulate a residency time of the fluid in the one or more cells.

In one or more embodiments, the method further comprises the step of measuring a temperature of the fluid flowing through the flow path.

In one or more embodiments, the method further comprises the step of measuring the temperature of the fluid at the outlet; and providing the temperature as feedback to a temperature controller configured to increase or decrease the heating of the fluid.

In one or more embodiments, the one or more one or more cells are serially arranged along the flow path.

In one or more embodiments, the method further comprises the step of not applying or varying the voltage across the one or more electrode pairs if the electrical conductivity, or specific conductance of the fluid falls outside a predetermined range.

In one or more embodiments, the inlet and outlet extend at substantially ninety degrees to each other.

In one or more embodiments, the method further includes providing a pump providing pressurized fluid in thermal communication with the one or more vehicle components.

In one or more embodiments, the method further includes providing a connection to a vehicle bus that communicates with other vehicle systems. The vehicle bus may include LIN (Local Interconnect Network) a very low cost in-vehicle sub-network.

In one or more embodiments, the battery voltage is in the range from about 250 to about 450 VDC.

In one or more embodiments, the one or more cells for retaining a fluid is made from an electrically non-conductive light weight plastic material.

In one or more embodiments, the one or more electrode pairs are rated to be operable up to about 9 kW.

According to another aspect of the present invention, there is provided a method for heating a vehicle component, the method comprising the steps of: passing a fluid along a flow path from an inlet to an outlet, the flow path including at least first and second cells positioned along the flow path such that the fluid passing the first cell subsequently passes the second cell, each cell including at least one electrode pair between which an electric current is passed through the fluid to produce heat therein during its passage along the flow path, and wherein at least one of the cells includes at least one segmented electrode, the segmented electrode comprising a plurality of electrically separable segments allowing an effective surface area of the segmented electrode to be controlled by selectively activating the segments such that upon application of a voltage to the activated electrode segment(s), current drawn will depend in part upon the effective surface area; determining the fluid conductivity, or specific conductance at the inlet; determining from measured fluid conductivity, or specific conductance a required voltage and current to be delivered to the fluid by the first cell to raise the temperature of the fluid therein by a first amount; determining a heated fluid conductivity, or specific conductance resulting from operation of the first cell; determining from the heated fluid conductivity, or specific conductance a required voltage and current to be delivered to the fluid by the second cell to raise the temperature of the fluid therein by a second amount; activating segments of the segmented electrode in a manner to effect delivery of desired current and voltage by the segmented electrode; and transferring heat to one or more vehicle components via the outlet from the heated fluid.

In one of more embodiments, the outlet is coupled to a heat exchange system within the vehicle.

In one or more embodiments, the heat exchange system includes a plurality of valves for distributing thermal energy between the one or more vehicle components.

In one or more embodiments, the one of more vehicle components includes a high voltage battery used for vehicle propulsion in a hybrid vehicle or a battery electric vehicle (BEV).

### BRIEF DESCRIPTION OF DRAWINGS

The invention will now be described in further detail by reference to the accompanying drawings. It is to be understood that the particularity of the drawings does not superseded the generality of the preceding description of the invention.

FIG. 1 shows a block diagram of a plug-in electric vehicle fitted with fluid heaters for heating key vehicle components in accordance with an embodiment of the present invention;

FIG. 2 shows a simplified block diagram a system for heating a vehicle component passing n heating cells in accordance with an embodiment of the present invention; and

FIG. 3 shows a flowchart of a method for heating a vehicle component with a fluid passing n heating cells in accordance with an embodiment of the present invention.

### DETAILED DESCRIPTION

The invention is suitable for electric vehicles or “EVs” and it will be convenient to describe the invention in relation to that exemplary, but non-limiting, application.

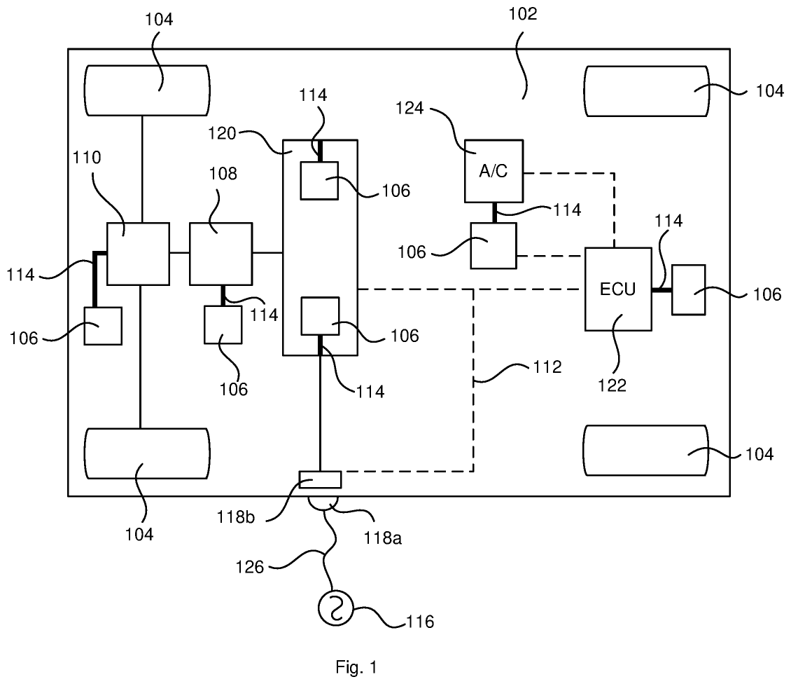

FIG. 1 shows an overall block diagram 100 of a plug-in electric vehicle 102 in accordance with an embodiment of the present invention. The vehicle 102 includes four wheels 104 driven by a DC motor 110 potentially via some additional drive components 108. The DC motor is powered by an internal power supply 120. In the embodiment shown, the internal power supply 120 is a is a rechargeable DC power supply and is formed of a combination of DC motor drive electronics and a battery such as a lithium ion battery, for example. The voltage of the internal power supply 120 is, for example, about 250 to 450 VDC. The internal power supply 120 is charged via an external power supply 116 via charge port 118a. Charging port 118b is an electric power interface for receiving electric power from external power supply 116 external to the vehicle 102. At the time of charging, a connector 118a of a charging cable 126 is connected to the charging port 118b.

Charging port 118b is electrically connected the internal power supply. When connector 118a is connected to charging port 118b, various interconnected electronic systems convert the electric power supplied from the external power supply 116 to that required by the internal power supply 120 and charges it. Those skilled in the art will recognise suitable designs for providing the stated charging functions, for example, one or more battery chargers, converters (DC/DC, AC/DC, and/or DC/AC), and/or inverters and the like.

The vehicle 102 may also contain components such as a heater and/or air conditioning equipment 124, Electronic Control Units (ECUs) 122, inverters, converters, and a power steering motor or pump (not shown), as is well known in the art. Modern vehicles utilize many ECUs to control operations of components such as engines, powertrains, transmissions, brakes, suspensions, onboard entertainment systems, communication systems, and the like. ECUs control basic operations of modern vehicles, from power steering to breaking to acceleration. In addition, some cars may be equipped with ECUs configured to provide advanced diagnostic features through on-board diagnostic (OBD) ports or over-the-air (e.g., using various types of wireless communication techniques). In the embodiment show, the ECU 122 is electrically connected to several vehicle components via a bus 112 for providing at least some of these stated purposes. To avoid an overly complex figure, the bus 112 is not shown as being connected to every vehicle component. However, in a modern vehicle, other components including the drivetrain would likely be connected to and OBD port.

In close proximity to each vehicle component 108, 110, 120, 122, 124 are one or more fluid heaters 106. The heaters 106 are thermally coupled to each vehicle component 108, 110, 120, 122, 124 via a heat exchange 114. The various possible configurations of the heat exchange 114 are known in the art.

The embodiment of FIG. 1 provides small fluid heaters 106 to effectively be coupled to the vehicle component being heated via the heat exchanger 114 without complex thermal loops or thermal circuits and the associated heat dissipation associated with said loops. For example, heat transfer paths and patterns need to be comprehensively designed to reduce undesirable heat losses, for which some improvements can be made based on theories and methodologies from thermal science, including positioning the heat source in close proximity to the component being heated, thereby avoiding heat loss on long conduction or convection paths.

However, it will be appreciated that less than six fluid heaters may be employed, in which case a thermal loop or thermal circuit may be employed including a circulating fluid, one or more pumps, one or more heat exchangers, and optionally valves to control flow. In some examples, the thermal loop optionally includes a port to fill the loop with fluid, and also optionally a reservoir tank. The thermal loop functions to transport and direct heat to or from the vehicle components, particularly the battery, and, if necessary, redirect this heat to another loop or directly to ambient air.

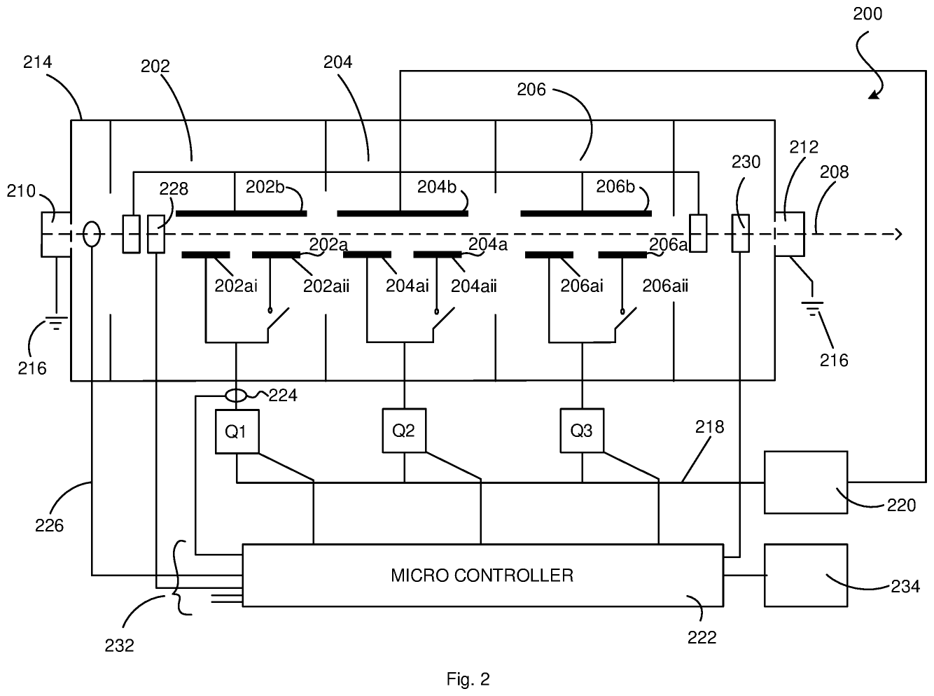

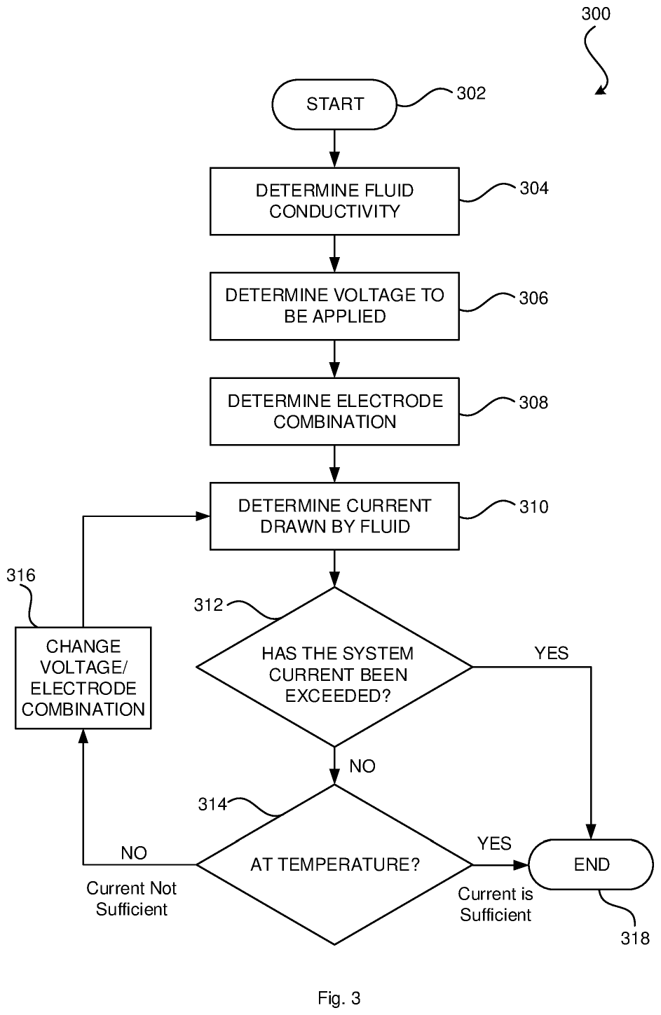

The fluid heaters 106 are used to heat fluid that is circulated between the fluid heaters 106 and their respective heat exchanges 114 using a small pump. The heat exchanger 114 is used to transfer heat to the vehicle components being heated. The level of heat transferred is controlled by the fluid heaters 106 and a controller, which will be discussed in greater detail with reference to FIGS. 2 and 3.

In this, or similar embodiments, the fluid heaters 106 uses multiple electrode sections, and heats fluid through the direct application of electrical energy into the fluid to cause heating within the fluid itself under electronic control.

The fluid heater voltage is provided by an internal power supply 120 or the external power supply 116 and manages a set fluid flow rate and changes in fluid conductivity. Being a closed loop continuous flow fluid heater, with fluid flow facilitated via a pump, the fluid heater 106 operates within constrained ranges of variation of temperature and conductivity. Depending on the outside temperature, vehicle components may be preconditioned to a certain temperature level when the vehicle is connected to the external power supply 116 for charging. The interior can be preconditioned independently of the external power supply 116.

FIG. 2 shows a simplified block diagram of a system for heating a fluid 200 according to an embodiment of the present invention. A fluid is caused to flow through three heating cells 202, 204 and 206 arranged along a flow path 208. The flow path 208 includes an inlet 210 to the heating cells 202, 204 and 206 and an outlet 212 from the heating cells 202, 204 and 206. The inlet and outlet extend at substantially one hundred and eighty degrees to each other, but other configurations may be conceived. The heating cells 202, 204 and 206 retain the fluid as it passes through the flow path and those skilled in the art will recognise suitable designs for providing the stated functions, for example, a tube or pipe.

In one or more embodiments, the heating cells 202, 204 and 206 are housed in, or integral with, a body 214. The body 214 is preferably made from a material that is electrically non-conductive and lightweight, such as synthetic plastic material. Advantageously, this makes the system very lightweight (in the order of 1.7 kg) which is desirable in automotive applications. However, the body 214 may be connected to metallic fixings, such as copper pipes or nipples, that are electrically conductive. Accordingly, earth connections 216 shown in FIG. 2 are included at the inlet 210 and outlet 212 of the body 214 so as to electrically earth any metal tubing connected to the system 200. The earth connections 216 would ideally be connected to an electrical earth of the vehicle in which the heating system of the embodiment was installed. As the earth connections 216 may draw current, by virtue of electrode voltage, through water passing through the system 200, activation of an earth leakage protection will occur. The system 200 includes earth leakage protection circuits. As will be appreciated by those skilled in the art, earth leakage protection circuits are designed to detect minimal earth leakage currents and further disconnect the power supply from a downstream circuit, in order to protect personnel or equipment from these currents.

It will also be appreciated that in automotive applications the system 200 may be required to adhere to various safety standards including ISO 16750-2:2010(E) that require electrical systems included in electric vehicles to undergo insulation resistance tests. For example, the system 200 may need to pass a test that ensures a minimum value of ohmic resistance required to avoid current between galvanically isolated circuits, where isolation is achieved by either inductive or capacitive means, and conductive parts of the system 200. Such a test may give an indication of the relative quality of the insulation system that includes the body 214 material. Being able to manufacture the body 214 from an electrically non-conductive plastic material provides a significant advantage to the prior art heaters described in the background section.

In the embodiment shown, the flow path 208, is provided with three heating cells 202, 204 and 206 including respective sets of electrode pairs 202a, 204a and 206a. However, it will also be appreciated that additional or fewer heating cells can be used. The electrodes may be metal or a non-metallic conductive material such as conductive plastics material, carbon, carbon impregnated material or the like.

It is important that the electrode substrate and coatings are selected from a group of electrically conductive materials (or combinations of materials) to minimise chemical reaction and/or electrolysis while heating water, ethylene glycol mixture.

The electrode pairs may also be manufactured from an electrically conductive, inert material such as graphite, carbon and combinations thereof. They may also be manufactured such that they are sectioned into different electrodes but share a common substrate or the like.

In one or more embodiments, one electrode of each electrode pair 202a, 204a and 206a is segmented into two or more segments, each segment being configured to individually apply voltage. The segmented electrode of each electrode pair 202a, 204a and 206a, is connected to a common switched electrical supply path 218 via separate voltage supply power control devices Q1, Q2, . . . , Qn, while the other of each electrode pair 202b, 204b and 206b are connected to the incoming DC voltage supply 220 respectively. The separate voltage supply power control devices Q1, Q2, . . . , Qn switch the common electrical supply in accordance with the power management control provided by the controller 222. The controller 222 may include a microprocessor that interacts with other components of the system 200 to regulate or measure the flow rate of the fluid, detect earth leakages, measure the temperature at the inlet 210 and/or outlet 212 (or at other positions along the flow path 208), and/or measure the current drawn 224 by the fluid at the heating cells 202, 204 and 206 (or at other positions along the flow path 208).

Electrical current supplied to heating cell 202, which may also be supplied to heating cells 204 and 206, is measured by current measuring device(s) 224. Only one current measuring device 224 is shown. However, it will be appreciated that the current at each heating cell 202, 204 and 206 may be measured by individual current measurement devices 224. For example, current measurements made by a hall current sensor electrically connected the output of power control devices Q1, Q2, . . . , Qn are communicated to the power management controller 222.

In one or more embodiments, the current measuring devices 224 are coupled to the power control devices Q1, Q2, . . . , Qn so as to be operable to determine the current being drawn from the DC power supply 220 by the fluid. A current amplifier may be used to amplify the output signal of the current measuring devices 224. The amplified signal is then received by the controller 222 and is compared with a threshold level. The calculated current threshold level will typically be set as a range of ampere, so that the current drawn by the fluid remains equal to or as close as equal to the threshold level only when the fluid is flowing through the flow path 208. While the system 200 is in use, the controller 222 will continue to compare the current measuring device(s) 224 output with the threshold level and make appropriate adjustments to the selection of combinations of electrode pairs, as well as making appropriate adjustments to the voltage supplied to the electrode pairs 202a, 204a and 206a so as to maintain a substantially constant current to heat the fluid, while consistently ensuring that the current handling capability of the electrical supply is not exceeded. However, when the system 200 enters a state of non-use, such as entering a standby mode, the controller 222 will remove the voltage applied to the heating cells 202, 204 and 206 accordingly.

By way of non-limiting example, the current measuring device(s) 224 may be able to sense, slight increases in the detected flow of electrical current through the fluid so as to determine the ideal voltage to apply across the electrode pairs 202a, 204a and 206a to heat the fluid. That is, the current measurement(s) are supplied as an input signal via input interface 224 to controller 222 which acts as a power supply controller.

In one or more embodiments, the controller 222 may also receive signals via input interface 224 from a flow rate measurement device or flow switch incorporating flow rate limiting 226 located near the inlet 210 to the body 214. The volume of the fluid passing between any set of electrodes 202a, 204a and 206a may be accurately determined by measuring the flow rate. Similarly, the residency time for which a given volume of the fluid will receive electrical power from the electrodes may be determined by measuring the flow rate of the fluid through the passage. It will be appreciated that the flow rate may be limited by one or more threshold values associated with the flow rate and/or the pumping or regulation of the fluid.

Heating of the fluid results from it being exposed to the electrodes (as described above) in the heating cells. Heating is promoted by providing the required current to be drawn by the fluid. In this application, the specific conductance of the fluid (for example, a water and ethylene glycol mixture) is in the range of from about 2,500 to 5,000 μS/cm i.e., significantly greater than that of water. This means that the electrodes may be significantly smaller than those that may be used to heating water, this is compounded by the very high-power supply voltage-given that electric vehicles operate at very high DC voltages, anywhere from about 250 to about 450 VDC. It will be appreciated that other mixtures of glycols, including propylene glycol as well as glycerol, trimethylolpropane, hexanetriol, pentaerythritol, and the like may also be suitable.

Accordingly, the current flowing through the fluid can be used as a measure of the electrical conductivity, or the specific conductance of that fluid and hence allows determination of the required change in applied voltage and electrode combinations selected required to keep the electric current drawn adequate for heating and maintaining that heat extremely efficiently.

The electrical conductivity and hence the specific conductance of the fluid will change with rising temperature, thus causing a specific conductance gradient along the path of fluid flow 208. In one or more embodiments, the controller 222 also receives signals via signal input interface 224 from an input temperature measurement device 228 to measure the temperature of the fluid at the inlet 210. An output temperature measurement device 230 may also be provided for measuring the temperature of the fluid at the outlet 212. Signals from the input temperature measuring device 228, and the output temperature measurement device 230 are provided as feedback to the controller 222 to allow the fluid temperature correctly calculated, and to also be continuously monitored.

The system 200 of the present embodiment is further capable of adapting to variations the fluid conductivity, or specific conductance, whether arising from the particular location at which the system is installed or occurring from time-to-time at a single location or by virtue of changes in the fluid temperature. In this regard the fluid conductivity, or specific conductance is determined as being directly proportional to the electric current drawn by the fluid flowing through the heating cells 202, 204 and 206. Advantageously, these changes can also be interpreted by the controller 222 and used for diagnostic purposes. For example, a lower than expected conductivity of the water and ethylene glycol mixture may indicate a poor-quality ethylene glycol or similar. An indication of this could be sent by the controller 222 to an ECU configured to provide advanced diagnostic features through OBD ports or over-the-air (e.g., using various types of wireless communication techniques) 234. Other diagnostic information may be sent in this manner including but not limited to inlet temperature, outlet temperature, power usage rate, fluid quality and conductivity increases or deterioration, power consumption, voltage, flow fare, error codes and other diagnostic information, and the like. Similarly, the controller 222 may also receive information from the vehicle including but not limited to set maximum applied power levels, co-ordinate power consumption with other device, set maximum and minimum fluid temperature limits, change temperature settings while in operation or in standby, error and failure management information, on or off messages.

Variations in the fluid conductivity, or specific conductance will cause changes in the amount of electrical current drawn by each electrode for a given applied voltage. This embodiment monitors such variations and ensures that the system 200 draws a desired level of current by using the determined conductivity, or specific conductance value to initially select a commensurate combination of electrode segments before allowing the system to operate. The electrodes represented by 202a, 204a, 206a are segmented into a number of electrode segments, 202ai and 202aii, 204ai, 204aii, 206ai, and 206aii.

For each respective electrode, the ai segment is fabricated to typically form about one third or two thirds of the active area of the electrode, the aii segment is fabricated to typically form about two thirds or one third of the active area of the electrode and so on. Selection of appropriate segments or appropriate combinations of segments thus allows the effective area of the electrode to be any one of three available values for electrode area. Consequently, for highly conductive fluids a smaller electrode area may be selected so that for a given voltage the current drawn by the electrode is prevented from rising above desired or safe levels, while yet maintaining the required current to be drawn to heat the fluid. Conversely, for poorly conductive fluids, a larger electrode area may be selected so that the required current will be drawn to affect the desired heating. Selection of segments can be simply made by activating or deactivating the power switching devices Q1, . . . . Qn as appropriate.

In particular, the combined surface area of the selected electrode segments is specifically calculated to ensure that the rated maximum electrical current values of the electrical supply system are not exceeded.

In one or more embodiments, the controller 222 receives the various monitored inputs and performs necessary calculations with regard to electrode active area selection, desired electrode pair voltages and currents to heat the fluid flowing through the flow path 208. The controller 222 controls the supply of voltage from either of internal DC power supply or the external power supply (as described with reference to FIG. 1), connected to each of the electrode sections 202, 204 and 206.

The voltage supply is separately controlled by the separate control signals from the controller 222 to the power switching devices Q1, . . . , Qn. It will therefore be appreciated that, based upon the various parameters for which the controller 222 receives representative input signals, a computing means under the control of a software program or firmware within the controller 222 calculates the control pulses required by the power switching devices in order to supply the required voltage to impart the desired temperature of the fluid flowing through the flow path 208, as will be discussed with reference to FIG. 3. Pulse width modulation (PWM) control is not required, although the controller 222 can be configured to accepted modulated signals. This is because the system 200 inherently applies the thermal heat equation based on the requirements as determined by the vehicle's control system. This system 200 may then dynamically change requirements according to the thermodynamic load of the battery, drive electronics, drive motor, cabin coolant heating system and the like.

In a number of embodiments, the controller 222 also converts readings from the current measuring device(s) 224, temperature sensors 228 and 230, flow rate measurement device or flow switch incorporating flow rate limiting 226, power switching devices Q1, . . . , Qn etc. into digital values and communicates messages based on those digital values to a digital communication device 232. It should also be appreciated that filtering methods can also be used, such as those, but not limited to including, moving average filters, evenly weighted moving average filters, the like, or a combination of these filters, which may be particularly suitable for implementation in firmware. The messages can then be sent to other devices (e.g., computers, smartphones, tablets, laptop computers, desktop computers, server computers, among other forms of computer systems) via a hardwired digital communication service, such as, but not limited to, vehicle BUS technology, Ethernet, RS485 or the like, or a wireless connection such as 802.11 Wi-Fi network or Bluetooth™ for processing by an application 234 or cloud computing platform. Advantageously, this can provide remote monitoring and/or configuration of the system 200, making it convenient for operators to modify parameters, such as flow rates or electrical power, based on the properties of the fluid being heated. For example, decreasing the flow rate and/or increasing the temperature when solution conductivities are low. In addition, system maintenance and management can also be facilitated via the digital communication method adopted.

It will be appreciated that various control implementations are possible. For instance, the system 200 may include, in a number of embodiments, an artificial intelligence-based control mechanism, which may in use, in part, cloud-based services. As noted, the decision whether to increase or decrease the flow rate (i.e., increasing or decreasing the residency time the fluid stays in the heating cells) or voltages (and subsequent current draw) may be based on multiple sensor inputs through interface 224 provided to the controller 222 (or to another platform via wireless transceiver 232). This coordination of communication and calculations may occur automatically, within the controller 222, an application 234 or an application hosted in the cloud. Further, the controller 222 may implement machine-learning based on the input data. Based on this information, the system 200 may pre-emptively make changes to the flow rate, voltages, temperature and the like.

It will be appreciated that the communication can be carried out using any suitable digital communication protocols, including, but not limited to AFDX, ARINC 429, Byteflight, CAN (Controller Area Network) an inexpensive low-speed serial bus for interconnecting automotive components, D2B (Domestic Digital Bus) a high-speed multimedia interface, FlexRay a general purpose high-speed protocol with safety-critical features, IDB-1394, IEBus, I2C, ISO 9141-1/-2, J1708 and J1587, J1850, J1939 and ISO 11783 an adaptation of CAN for commercial (J1939) and agricultural (ISO 11783) vehicles, Keyword Protocol 2000 (KWP2000) a protocol for automotive diagnostic devices (runs either on a serial line or over CAN), LIN (Local Interconnect Network) a very low cost in-vehicle sub-network, SMARTwireX, SPI, VAN (Vehicle Area Network), UAVCAN (Uncomplicated Application-level Vehicular Communication And Networking), Wi-Fi 802.11, 6LowPan/ZIGBEE™ 802.15, Ethernet 802.3, 802.11 and 802.15.4, and RS485. That may include a bus, a cable, a wireless communication channel, a radio-based communication channel, the Internet, a local area network (LAN), a wireless local area network (WLAN), a wide area network (WAN), a cellular communication network, or any Internet Protocol (IP) based communication network and the like. In a preferred embodiment, the communication is carried out using the LIN bus. The LIN bus is an inexpensive serial communications protocol, which effectively supports remote application within a car's network. It is particularly intended for mechatronic nodes in distributed automotive applications, but is equally suited to industrial applications. It is intended to complement the existing CAN network leading to hierarchical networks within cars.

The wireless transceiver 232 may also be adapted to facilitate communication between a remote firmware update mechanism and the controller 222. As will be appreciated by those skilled in the art, the remote firmware update mechanism together with the controller 222 may be adapted to periodically check for updates from a remote repository, download firmware updates and to compare downloaded firmware to existing firmware to determine the necessity of installing the downloaded firmware and the like.

FIG. 3 shows a flowchart of a method for heating a fluid in accordance with an embodiment of the present invention, including the embodiments discussed with reference to FIG. 2.

The method 300 starts at start block 302, at step 304 the electrical conductivity, or specific conductance of a fluid is determined at the inlet to a first heating cell including a first electrode pair. In one or more embodiments, the electrical conductivity, or specific conductance is determined by the amount of current drawn by the fluid while an initial voltage is applied across the first electrode pair from a voltage supply power control device (i.e., Q1 as discussed with reference to FIG. 1).

At step 306, from the electrical conductivity, or specific conductance of the fluid a voltage to apply across the first electrode pair at a current sufficient to heat the fluid to the set temperature is determined. At step 308, the electrode segment combination is determined. For example, where the segmented electrode is divided into three segments, the segments may have relative effective areas in a ratio of 1:2:4, that is, the segments preferably constitute four sevenths, two sevenths and one seventh of the total effective electrode area, respectively. In one or more embodiments, all of the segments may be activated for fluids that are of relatively low conductivity, or specific conductance, and one or more of the segments may be activated for fluids that are of relatively high conductivity, or specific conductance.

Once the applied voltage and electrode segment combination has been determined, the current drawn by the fluid is then measured at step 310.

At step 312 it is determined whether the current limit of the system has been exceeded. If the system current limit has exceeded the limit, the process ends at step 318. If the system current limit has not exceeded the limit, at step 314 it is determined whether there is sufficient current to heat the fluid to a set temperature.

In one or more embodiments, the method returns over step 316 such that the electrical conductivity, or specific conductance is continuously determined and appropriate adjustments to the voltages supplied and electrode segment combinations in all heating cells 202, 204 and 206 are made so as to maintain a substantially constant current to maintain the fluid at a set temperature. Advantageously, by returning over step 316 the method is capable of adapting to variations in the fluid's conductivity, or specific conductance, whether arising from the changed concentration of ethylene glycol and water mixture or particular quality of the ethylene glycol that may occur from time-to-time or based on a particular location.

In one or more embodiments, steps 310 to 316 may be repeated for n heating cells until the method ends at step 318.

It will be appreciated that some embodiments may be comprised of one or more generic or specialized controllers or processors (or “processing devices”) such as microcontrollers, microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

The term “coated”, as used herein with reference to “coated electrodes”, may refer to the attachment of a material on the outer surface of another material. The attachment may be partial or whole coverage of the surface of the other material and may be by any mechanical, chemical, or other force or bond.

The term “manufactured” may refer to production of one or more electrode pairs that can be manufactured from an electrically conductive, inert material such as graphite, carbon and combinations thereof.

The term “heat exchanger”, as used herein may refer to a device for transferring heat from one medium to another. Examples of heat exchangers include radiators, which can include coils, plates, fins, pipes, and combinations thereof.

The term “fluid”, as used herein may refer to gases, liquids, gels and combinations thereof. A cooling fluid, or coolant, assists in transferring heat within a thermal circuit. In some examples, a solid conductor may be substituted for a heat transfer fluid.

The term “thermally coupled”, as used herein may refer to two or more components or devices in communication, such that they are capable of exchanging (i.e., receiving or dissipating) heat between two or more of the components or devices. Thermally coupled devices can be in close proximity or separated by pipes or other medium for transferring or exchanging heat.

The term “thermal loop,” as used herein may refer to a circuit including at least a circulating fluid, one or more pumps, a heat exchanger, optionally an electric fluid heater, and optionally valves to control flow. In some examples, the thermal loop optionally includes a port to fill the loop with fluid, and also optionally a reservoir tank. The thermal loop functions to transport and direct heat to or from the battery and, if necessary, reject this heat to another loop or directly to ambient air.

The term “powertrain”, as used herein may refer to one or more of an engine, battery, electric motor(s), motor power electronics, battery power electronics, on-board battery charger, and DC-DC converters.

As used herein, “drivetrain”, refers to the system in a motor vehicle that connects the transmission to the drive axles. A hybrid vehicle can include an electric drivetrain, for example.

Where the terms “comprise”, “comprises”, “comprised” or “comprising” are used in this specification (including the claims) they are to be interpreted as specifying the presence of the stated features, integers, steps or components, but not precluding the presence of one or more other features, integers, steps or components, or group thereof.

While the invention has been described in conjunction with a limited number of embodiments, it will be appreciated by those skilled in the art that many alternative modifications and variations in light of the foregoing description are possible. Accordingly, the present invention is intended to embrace all such alternative, modifications and variations as may fall within the spirit and scope of the invention as closed.

1. A system for heating a vehicle component, the system comprising:
one or more cells for retaining a fluid, each cell including one or more electrode pairs positioned therein;
the one or more cells arranged along a flow path including an inlet to and an outlet from the one or more cells;
a controller configured to:
regulate the flow of the fluid from the inlet to the one or more cells;
determine at the one or more cells the electrical conductivity, or specific conductance, of the fluid;
determine from the electrical conductivity, or specific conductance, of the fluid a voltage to apply from a high voltage battery, or an external power source located outside of the vehicle, across the one or more electrode pairs at a current sufficient to heat the fluid therein; and
pass the current from the one or more electrode pairs to the fluid to produce a heated fluid, wherein the heated fluid transfers heat to one or more vehicle components via the outlet.

2. The system of claim 1, wherein the one or more cells for retaining the fluid are in proximity to the one or more vehicle components.

3. The system of claim 1, wherein the one or more vehicle components includes one of more of the high voltage battery, a DC motor, a transmission, a heating, ventilation, and air conditioning (HVAC) system, and drive electronics.

4. The system of claim 1, wherein the specific conductance of the fluid is greater than that of water.

5. (canceled)

6. The system of claim 1, wherein the fluid includes a water and ethylene glycol mixture.

7. The system of claim 6, wherein the controller monitors properties of the mixture including ethylene glycol quality or water and ethylene glycol mixture concentration.

8. The system of claim 6, wherein the controller monitors properties of the mixture including ethylene glycol quality or water and ethylene glycol mixture concentration by measuring the electric current drawn by the mixture.

9. The system of claim 6, wherein the controller monitors ethylene glycol quality or water and ethylene glycol mixture concentration to maintain the desired thermal conductivity of the mixture.

10. The system of claim 6, wherein the controller is configured to manage the thermal conductivity of the mixture by monitoring the ethylene glycol quality and the water and ethylene glycol mixture concentration.

11. The system of claim 6, wherein the controller is configured to manage the thermal conductivity of the mixture thereby ensuring that an optimum operating temperature of the one or more vehicle components is maintained.

12. (canceled)

13. The system of claim 1, wherein the controller is further configured to determine the electrical conductivity, or specific conductance of the fluid and thereby determine the voltage to apply across the one or more electrode pairs continuously.

14. The system of claim 1, wherein the one or more electrode pairs are segmented into two or more segments, each segment being configured to individually apply voltage by the controller.

15-30. (canceled)

31. The system of claim 1, further including a pump providing pressurized fluid in thermal communication with the one or more vehicle components.

32. The system of claim 1, wherein the controller includes a vehicle bus that communicates with other vehicle systems.

33. (canceled)

34. The system of claim 1, wherein the one or more cells for retaining a fluid is made from an electrically non-conductive light weight plastic material.

35. (canceled)

36. A method for heating a vehicle component, the method comprising the steps of:
providing an electrical connection to a high voltage battery being at least partially used for vehicle propulsion;
providing one or more cells for retaining a fluid, each cell including one or more electrode pairs positioned therein;
arranging the one or more cells along a flow path, the flow path including an inlet to and an outlet from the one or more cells;
determining at the one or more cells the electrical conductivity, or specific conductance, of the fluid;
determining from the electrical conductivity, or specific conductance, of the fluid a voltage to apply from the high voltage battery, or an external power source located outside of the vehicle, across the one or more electrode pairs at a current sufficient to heat the fluid therein; and
passing the current from the one or more electrode pairs to the fluid to produce a heated fluid, wherein the heated fluid transfers heat to one or more vehicle components via the outlet.

37. The method of claim 36, wherein the one or more cells for retaining the fluid are provided in proximity to the one or more vehicle components.

38. The method of claim 36, wherein the one or more vehicle components includes one of more of the high voltage battery, a DC motor, a heating, ventilation, and air conditioning (HVAC) system, and drive electronics.

39. The method of claim 36, wherein the specific conductance of the fluid is greater than that of water.

40. (canceled)

41. The method of claim 36, wherein the fluid includes a water and ethylene glycol mixture.

42. The method of claim 41, further comprising the step of monitoring properties of the mixture including ethylene glycol quality or water and ethylene glycol concentration.

43-64. (canceled)

65. The method of claim 36, wherein the one or more cells for retaining a fluid is made from an electrically non-conductive light weight plastic material.

66. (canceled)

67. A method for heating a vehicle component, the method comprising the steps of:
passing a fluid along a flow path from an inlet to an outlet, the flow path including at least first and second cells positioned along the flow path such that the fluid passing the first cell subsequently passes the second cell, each cell including at least one electrode pair between which an electric current is passed through the fluid to produce heat therein during its passage along the flow path, and wherein at least one of the cells includes at least one segmented electrode, the segmented electrode comprising a plurality of electrically separable segments allowing an effective surface area of the segmented electrode to be controlled by selectively activating the segments such that upon application of a voltage to the activated electrode segment(s), current drawn will depend in part upon the effective surface area;
determining the fluid conductivity, or specific conductance at the inlet;
determining from measured fluid conductivity, or specific conductance a required voltage and current to be delivered to the fluid by the first cell to raise the temperature of the fluid therein by a first amount;
determining a heated fluid conductivity, or specific conductance resulting from operation of the first cell;
determining from the heated fluid conductivity, or specific conductance a required voltage and current to be delivered to the fluid by the second cell to raise the temperature of the fluid therein by a second amount;
activating segments of the segmented electrode in a manner to effect delivery of desired current and voltage by the segmented electrode; and transferring heat to one or more vehicle components via the outlet from the heated fluid.

68-70. (canceled)
